(19) United States
(12) Patent Application Publication
(10) Pub. No.: US 2020/0027716 A1
(43) Pub. Date: Jan. 23, 2020

(54) Method of Manufacturing an Insulation Layer on Silicon Carbide and Semiconductor Device

(71) Applicant: ZF Friedrichshafen AG, Friedrichshafen (DE)

(72) Inventor: Yuji Komatsu, Kawasaki-City (JP)

(21) Appl. No.: 16/336,244

(22) PCT Filed: Aug. 8, 2017
(86) PCT No.: PCT/EP2017/069985

§ 371 Date: Mar. 25, 2019

(30) Foreign Application Priority Data
Sep. 26, 2016 (DE) 10 2016 218 405.9

(51) Int. Cl. H01L 21/02; H01L 29/16; H01L 21/3105; H01L 29/78

(52) U.S. Cl. CPC H01L 21/0228; H01L 29/7802; H01L 21/3105; H01L 29/1608

(57) ABSTRACT

A method of manufacturing an insulation layer on a silicon carbide substrate, the method including preparing a surface of a silicon carbide substrate, forming a first part of an insulation layer on the surface of the silicon carbide substrate at a temperature below 400° Celsius, and forming a second part of the insulation layer by depositing a dielectric film on the first part of the insulation layer.

### FIELD OF THE INVENTION

The present invention relates generally to a method of manufacturing an insulation layer on silicon carbide and a semiconductor device.

### BACKGROUND

U.S. Pat. No. 7,880,173 B2 discloses a semiconductor device and method of manufacturing such a device. It discloses that a gate insulation layer is formed on a silicon carbide substrate. It explains that the gate insulation layer is formed by oxidization of the surface of silicon carbide in an atmosphere containing O₂ or H₂O at a temperature within the range of 800° Celsius to 1200° Celsius and has a thickness of approximately 50 nanometers. Alternatively it teaches the use of a low temperature oxide which was formed by reacting silane and oxygen at 400° Celsius to 800° Celsius to deposit silicon oxide on the silicon carbide substrate.

US 2011/0169015 A1 also discloses a semiconductor device and method of manufacturing such a device. It discloses that a surface protective film is formed on a silicon carbide substrate. It explains that the surface deactivation layer of the surface protective film is formed by oxidation of the surface of silicon carbide in an atmosphere containing O₂ and H₂O at a temperature of 1000° Celsius for 1 to 4 hours and has a thickness of approximately 10 nanometers. The formation of the surface deactivation layer is followed by the deposition of silicon oxide containing phosphorus and further deposition of silicon nitride to formulate the surface protective film. This surface protective film is also an insulation layer on silicon carbide.

### SUMMARY OF THE INVENTION

A method of manufacturing an insulation layer on silicon carbide and a semiconductor device according to the present subject matter exhibit the following advantages over the above cited prior art:

Due to the forming of an insulation layer lower than 400° Celsius according to the present subject matter, the thermal stress is much less after cooling down to room temperature than in the prior art. This improves for example the electrical performance of a transistor device like MOSFET (metal-oxide-semiconductor field effect transistor) or BJT (bipolar junction transistor) which is made of silicon carbide. A dielectric film according to the present subject matter can exhibit a high dielectric constant which is potentially beneficial to the performance of for example a MOSFET. By providing a first part of an insulation layer between the substrate of the silicon carbide and the dielectric film, instead of directly depositing the dielectric film on the silicon carbide, an improved interface quality is realized.

The dielectric film consists of materials like aluminum oxide, hafnium oxide, hafnium silicide, hafnium aluminum oxide, zirconium oxide, zirconium silicide, titanium oxide, lanthanum oxide, silicon nitride or deposited silicon oxide. The insulating layer consists of two layers including a thin silicon oxide layer formed by oxidizing the silicon carbide surface and another dielectric film deposited on the thin silicon oxide layer.

In addition, the first part of the insulation layer on the surface of the silicon carbide is realizable with available technology without too much additional cost.

Moreover, the method according to the present subject matter and the semiconductor device according to the present subject matter show considerable advantages over cited prior art and lead, for example, to a much improved transistor device made of silicon carbide.

In one embodiment, the method of manufacturing an insulation layer on silicon carbide consists of steps in different machines. In some embodiments, the method of manufacturing an insulation layer on silicon carbide is an automated process, but it is possible to do some or all steps manually. In several embodiments, manufacturing means that the insulation layer on the silicon carbide is formed by oxidizing the silicon carbide followed by depositing another dielectric film.

Silicon carbide is a semiconductor which is used for high power and/or high temperature applications. Silicon carbide devices can carry a high current density and work under conditions with high temperature or/and high radiation. Especially for MOSFETs which are well known from other semiconductors, like silicon or gallium arsenide, are used in a wide range of applications. It is also the same for BJTs. Silicon carbide could also be used for light emitting or light receiving semiconductor devices such as light emission diodes or photo diodes especially using blue light.

In one embodiment, a transistor device made of silicon carbide is manufactured using the following technologies: When manufacturing a transistor device out of silicon carbide, a polytype called 4H—SiC is normally preferred because its electrical property is suitable to perform as a transistor device especially for high power and/or high temperature applications. The ingot of 4H—SiC may be epitaxially grown on the seed crystal normally with a sublimation method. Unlike silicon, silicon carbide does not have liquid phase at a practical pressure, therefore the solidification of the melt is not available.

After a silicon carbide substrate is made of the ingot by slicing, at least one of the surfaces of the substrate may be polished mechanically and chemically. Above the polished surface, high-quality 4H—SiC layer is epitaxially grown at vapor phase using chemical reaction of silicon hydride and carbon hydride. During the epitaxial growth, several layers are grown, where each of the layers has a certain thickness and a different impurity doping which designates the conducting type (p-type or n-type) and the conductivity of the layer. After the multi layers of silicon carbide are grown, part of the surface is excavated locally using dry or wet etching, and/or part of the surface gets further impurities doping locally using ion implantation or equivalent local doping method, with the help of surface patterning technologies like photolithography.

An insulating layer is formed to cover the exposed surface of the silicon carbide, and the layer is locally removed where the silicon carbide should be connected to the metal electrode. After the metal electrode is formed with an appropriate material of metal with an adequate size and thickness on each of the locally removed insulating layer, transistor devices are diced out of the substrate where multiple devices are formulated throughout the processes mentioned above. Each process step, like epitaxial layer, local etching, local doping, insulating layer patterning, and metal formation, is controlled according to the design of the finished device. In one embodiment, the semiconductor device is one of the above mentioned devices such as a MOSFET or a BJT. However, such examples should not be construed as limiting the semiconductor device to those devices. Instead, it should be appreciated that any device using an insulation layer could benefit from the present subject matter described herein.

An insulation layer is a layer which electrically insulates a metallization from the semiconductor. As such, there is no current flowing except unwanted currents like a leakage current. By using the electric field of the electric charges in the metallization, it is possible to influence the current flow in the semiconductor. Thus, controlling the current is possible. This is used for example in MOSFETs.

An insulation layer is also expected to deactivate the surface of the semiconductor. When the semiconductor surface is exposed, high density of surface states are formed causing a relatively large base current of a device like a BJT. Since a current gain (which is equal to principal current divided by base current) is an important performance factor of BJT, the base current is desired to be reduced. When the insulation layer properly deactivates the surface, the generation of surface states is suppressed and the base current, having a path at the surface, is significantly decreased. The improvement of the surface deactivation is important to the performance of a BJT.

The preparation of a surface of the silicon carbide normally includes the removal of silicon oxide, which is often the native oxide which exists due to the exposure of silicon carbide to air.

The native oxide is irregular in thickness and too thin to be usable for forming a reliable insulation layer. The native oxide is normally removed by 5-10% hydro fluoric acid (HF) solution.

Alternatively instead of native oxide, other type of silicon oxide could exist as a result of the previous processes.

When the previous process includes local doping by ion implantation, it must be followed by post-implantation high-temperature anneal to recover the crystal structure damaged by ion implantation and to activate the implanted species as donor or acceptor. A thin carbon capping film is often formed before this post-implantation to prevent surface roughening, and this carbon capping film must be removed by oxygen O₂ plasma or low temperature (700-800° Celsius) oxidation. This leaves a few nanometers of silicon oxide, but it is also unreliable to use for the gate insulating layer or the surface protective layer. This silicon oxide is also removable by 5-10% HF solution, but the HF concentration can be higher, e.g., up to 65%, to shorten the process time.

In another case, the previous process especially includes reactive ion etching (RIE) to make a trench structure or a mesa structure on the surface of the silicon carbide, a thick oxide is formed before the preparation, for example, using pyrogenic oxidation at a temperature 1000° Celsius or higher for longer than 5 hours, which is sometimes called as sacrificial oxidation because the layer sacrifices itself by the subsequent removal where ion bombardment damage was induced by the previous RIE process. After the removal of the thick oxide, the exposed surface and the near-surface layer of the silicon carbide are expected to consist of very high-quality crystal of silicon carbide which were isolated and protected from the ion bombardment. To remove the thick oxide, 5-10% HF is possible to use, but 50-65% HF is preferably used to shorten the process time.

Other preparation steps for cleaning and preparing the surface for the further steps could be included here. The use of photo lithography to define the surface on the silicon carbide could especially be included, for example. By using photolithography, it is possible to define the device structures on the surface of the silicon carbide in combination with etching, metallizing, deposition of dielectric films or growing silicon oxide.

The first part of the insulation layer on the surface is formed at a temperature lower than 400° Celsius, for example, at a temperature between 0 and 45° Celsius, such as room temperature at around 20° Celsius. This is a considerable advantage, since thermal stress or a deterioration of interfaces between different films or layers is reduced or even avoided. This process is also possible to be performed without a temperature controller like heater or chiller, leading to significant advantage of cost reduction in the manufacturing process.

In one embodiment, the first part of the insulation layer is a silicon oxide film or layer. However, in other embodiments, the first part of the insulation layer could be any other suitable layer.

The second part of the insulation layer is a dielectric film. Examples for this dielectric film are given above and not limited to those examples. The dielectric film is deposited using a known technology, for example by an atomic layer deposition or by a chemical vapor deposition. Other technologies of depositing the dielectric film include any other vaporization in a high vacuum or an electrodeposition in a fluid.

Atomic layer deposition (ALD) is a thin film deposition method in which a film is grown on a substrate by exposing its surface to alternate gaseous species. The species are never simultaneously present in the reactor, but they are inserted as a series of sequential, non-overlapping pulses. In each of these pulses the precursor molecules react with the surface in a self-limiting way, so that the reaction terminates once all the reactive sites on the surface are consumed. The deposition speed is relatively slow, but the high-quality of the film is expected especially to contribute to the higher breakdown field for the film material.

A chemical vapor deposition (CVD) has the elements or chemical substances that should be deposited in a chemical compound which reacts on the first part of the insulation layer on the surface of the silicon carbide with the deposition of this element or compound. This is possible in a very controlled manner so that the thickness of the dielectric film is properly controlled. ALD is included in CVD in a wider meaning.

The thickness of this dielectric film is 20 nanometers at thinnest and 1000 nanometers at thickest, which is dependent on the application of the transistor device. In case of MOSFET, a thinner dielectric film can increase the controllable range of the device while the risk of the breakdown of the gate insulator is increased. Therefore, the film is thinned according to the breakdown field, which is one of the properties of the film material, down to the minimum range where the breakdown is avoided. In case of BJT, the thickness of the film is preferably 150 nanometers or more, more preferably 150 nanometers to 1000 nanometers. A typical thickness of the metal electrode is 150 nanometers and the dielectric film should be preferably thicker than the metal to ensure the process to form the metal. A film thicker than 1000 nanometers does not increase the advantage in spite of the extended processing time.

An advantageous characteristic of the semiconductor device and the method of manufacturing the insulation layer on the silicon carbide according to the present subject matter is that the first part, especially the silicon oxide film, is very thin with a thickness between 0.5 nanometers and 10 nanometers. This layer deactivates the surface of the silicon carbide by terminating the dangling bonds which cause the generation of the surface states where electrons and holes are uncontrollably recombined. The effect of the surface deactivation suppresses the generation of the surface states, decreases the recombination of the electrons and holes, and thus enhances the controllability of the semiconductor device, therefore improving the performance of the device.

Another role of the thin silicon oxide is to protect the silicon carbide surface from the direct deposition of the dielectric film above. Although the film property is potentially desirable for its large dielectric constant or its high breakdown field, or for the deposition temperature being low enough to avoid the thermal stress after cooling down, the uncontrolled interface implemented by the direct deposition could often extinguish those desirable potentials. For example, fixed charges are accumulated near the interface in the deposited film, which causes the bending of the energy band of the silicon carbide near the interface, resulting in slowing down the moving speed of the electrons or holes. The thin oxide suitably accommodates the ground for the dielectric film deposition to avoid the accumulation of the fixed charges at the initial stage of the deposition. Therefore, the desired potentials described above are utilized without slowing down the speed of the electrons or the holes.

In some embodiments, the first part of the insulation layer, e.g. the silicon oxide layer, is only partly formed on the silicon carbide, for example on those parts necessary for forming a MOSFET or a BJT. It is also possible, in other embodiments, to cover the whole surface of the silicon carbide substrate with the insulation film, if it is needed or beneficial for the manufacturing process.

Another advantage is that the method could consist of using ozone or O₂ plasma which is brought into the contact with the surface to generate the silicon oxide film. Both ozone O₃ and O₂ plasma are powerful oxidants.

In alternative embodiments, a chemical solution is brought into contact with the surface. This chemical solution could be a liquid or a gas, so it is possible to rinse the silicon carbide with a chemical solution or even submerge the silicon carbide in the chemical solution, or have the chemical solution as a vapor. An example of a suitable chemical solution includes a solution containing nitric acid, hydrogen peroxide, sulfuric acid, hydrochloric acid, ozone, acetic acid, boiling water or ammonium hydride. This is not a concluding list. A typical solution is 68% nitric acid (HNO₃), which is widely circulated in commercial base and is also an effective oxidant at from 0° Celsius to its boiling point (121° Celsius). Even processing at room temperature, meaning neither heater nor chiller is required, for 30 minutes creates a silicon oxide that is approximately 1-nanometer thick. Processing at 100° Celsius to 121° Celsius creates the oxide more rapidly.

A further advantage is that, after having deposited the dielectric film, the insulation layer on the silicon carbide is annealed at a temperature of at least 50 Kelvin (K) higher than the peak temperature during the deposition of the dielectric film. This annealing step enhances the deactivation effect by the thin oxide of the silicon carbide surface. In most cases, the deposition of the dielectric film contains some kind of hydride gas, which leaves excess hydrogen inside the film. This excess hydrogen is released by the annealing at higher temperature than the deposition temperature, and helps the termination of the dangling bonds of the silicon carbide surface which are not yet terminated at the step of the thin oxide formation. The excess hydrogen also terminates the dangling bonds inside the thin oxide, which increases the break-down field of the thin oxide. The annealing is also effective to improve the quality of the deposited dielectric film itself. Besides excess hydrogen, there are very likely other unwanted byproducts generated by the contained materials for deposition. These byproducts are evaporated by annealing, and the film is increasingly purified.

An advantageous embodiment of semiconductor device according to the present subject matter is a MOSFET and a BJT. But it is possible to employ the described present subject matter in any other suitable device which needs such an insulation layer on the surface of silicon carbide.

### BRIEF DESCRIPTION OF THE FIGURES

Embodiments of the present subject matter are described below with reference to the appended figures. In the figures, the following is shown:

FIG. 1 shows a cross-section of a metal-oxide-semiconductor field effect transistor doped at least partially using diffusion (DMOSFET);

FIG. 2 shows a cross-section of a u-shaped metal-oxide-semiconductor field effect transistor (UMOSFET);

FIG. 3 shows a flowchart of one embodiment of a method of manufacturing an insulation layer on silicon carbide;

FIG. 4 shows a cross-section of the semiconductor device showing the preparation of the surface;

FIG. 5 shows a cross-section of the semiconductor device showing forming of the silicon oxide layer;

FIG. 6 shows an alternative method of forming the silicon oxide layer,

FIG. 7 shows the deposition of the dielectric film;

FIG. 8 shows flowchart of the another embodiment of a method of manufacturing an insulation layer on silicon carbide;

FIG. 9 shows a cross-section of a BJT;

FIG. 9a shows sequential steps of the inventive method for manufacturing a BJT;

FIG. 10 shows sequential steps of the inventive method for manufacturing a DMOSFET; and

FIG. 11 shows sequential steps of the inventive method for manufacturing a UMOSFET.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

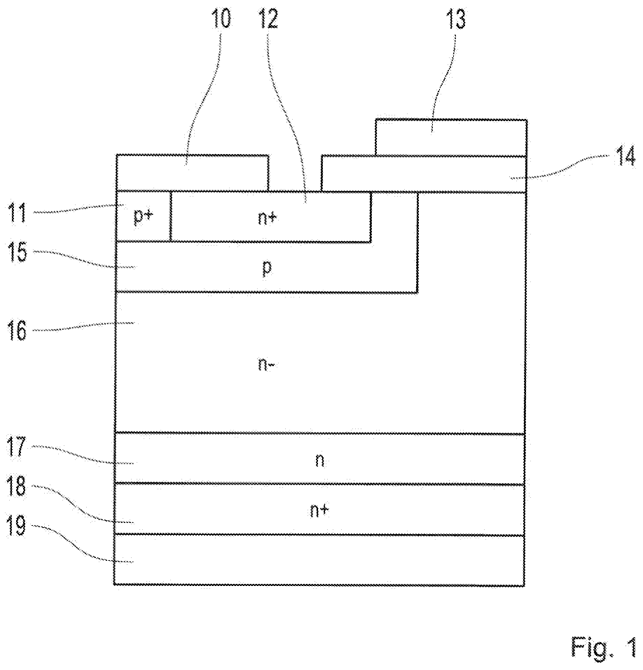

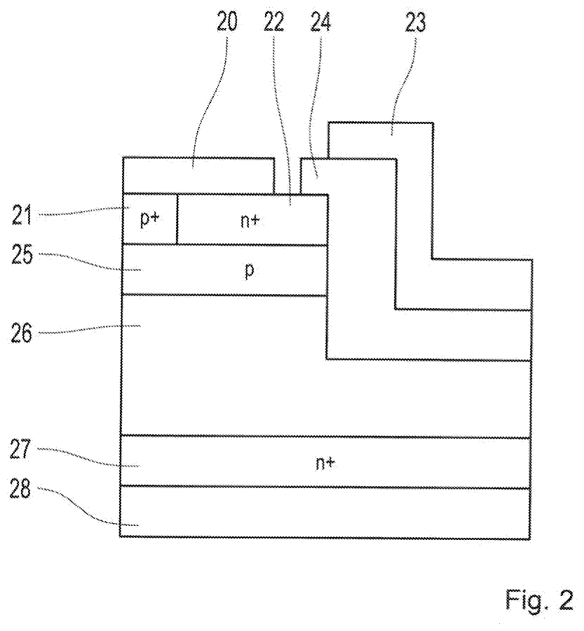

FIG. 1 shows a cross-section of a metal-oxide-semiconductor field effect transistor in which diffusion is at least partly used for doping the semiconductor and is hereinafter referred to as DMOSFET. FIG. 2 shows a cross-section of a metal-oxide-semiconductor field effect transistor according to the present subject matter having a U-shaped geometry and is hereinafter referred to as UMOSFET. The trench structure is normally formed by reactive ion etching (RIE).

As shown in FIGS. 1 and 2, both DMOSFET and UMOSFET consist of a MOSFET formed above a thick n− drift region 16, 26, with the n+ substrate 18, 27 serving as the drain terminal or electrode 19, 28. In FIG. 1, the DMOSFET structure consists of a p base region 15 on which a p+ contact region 11 and an n+ source region 12 are located. A source and base contact or electrode 10 is on top of the contact region 11 and part of the source region 12. A gate contact or electrode 13 is insulated by an insulating layer 14 which is made according to the present subject matter. The electrodes, base contact 10, gate contact 13, and drain terminal 19, are of a metal which is proven for being a good contact metal to silicon carbide. For example, the electrodes 10, 13, 19 can be made of nickel which is deposited using vaporization of nickel, or electrodeposition, or sputtering, or some other known method for depositing a metal film. The gate contact 13 made of metal, for example, nickel or gold, is deposited on the source region 12 formed of a dielectric film which according to the present subject matter is deposited on the insulating layer 14. The insulating layer 14 has a first part which is a silicon oxide layer on the lower side. The words layer and film are used interchangeably for each other in this text. According to the present subject matter the silicon oxide layer as the first part of the insulating layer 14 is 0.5 nanometers to 10 nanometers thick. The second part of the layer 14 is, for example, aluminum oxide made by ALD and typically has a thickness of 30 nanometers. And the metal gate contact 13 is for example several hundred nanometers thick as well. With the gate electrode 13, the current between source electrode 10 and drain electrode 19 is controlled.

In the UMOSFET structure shown in FIG. 2, the p base layer 25 and the characteristically shaped insulation layer 24 are on top of the n− drift layer 26, with insulation layer 24 having the first and second part according to the present subject matter and the gate metallization 23. On top of the p base layer 25, the contact p+ layer 21 and the n+ source layer 22 are located. The source electrode 20 made of nickel and gold is deposited on the p+ contact layer 21 and the n+ source layer 22.

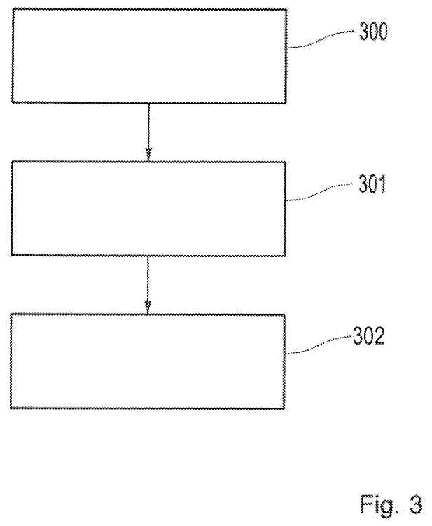

FIG. 3 shows a flowchart of manufacturing an insulating layer on the surface of the silicon carbide. The first step, at step 300, is preparing the surface of the silicon carbide for the further steps. The surface of the silicon carbide is usually prepared by removing the native oxide, the silicon oxide formed during the carbon cap removal process for post-implantation, or the sacrificial oxide which was damaged by ion bombardment during RIE and subsequently oxidized on the silicon carbide. The surface of the silicon carbide is prepared, for example, by using hydro fluoric acid (HF), which is normally dissolved in water. Alternative chemicals are usable for removing the residual oxidation layer, but hydro fluoric acid is well proven. The etching away of this oxide layer is achieved by HF dissolved in water or by hydro fluoric acid in a vapor.

At step 301, the forming of the first part of the insulation layer on the silicon carbide is performed. As explained above, the first part of the insulation layer is a silicon oxide film which is between 0.5 nanometers and 10 nanometers. The silicon oxide film could be grown below 400° Celsius, preferably between 0 and 45° Celsius. Ozone, or O₂ plasma, or any of the other chemicals listed above could be brought into contact with the surface to generate the silicon oxide film. For example, the surface of the silicon carbide may be brought into contact with 68% HNO₃ at room temperature (without heating or cooling) for 60 minutes, or 68% HNO₃ at 100-121° Celsius for 30 minutes. Both temperature range and duration range can be larger. When chemicals are used to grow the silicon oxide, rinsing with water, especially deionized water, and drying the substrate normally follow.

At step 302, the dielectric film is deposited on the first part of the insulation layer. The dielectric film could be made of, for example, aluminum oxide, hafnium oxide, hafnium aluminum oxide, hafnium silicide, zirconium oxide, zirconium silicide, titanium oxide, lanthanum oxide, silicon nitride, or silicon oxide. By having the first part of the insulation layer, which is the silicon oxide film, and the additional dielectric film, a good insulation is achieved for controlling the current flowing from source to drain by an electric field which is controlled over the gate electrode 13, 23. Atomic layer deposition may be advantageously used for forming the gate insulator, as atomic layer deposition provides excellent controllability of stoichiometry, thickness, and uniformity, and the gate insulator must be thin and uniform with high quality. Alternatively, chemical vapor deposition, which is sometimes enhanced by plasma, has an advantage of depositing closely packed film with relatively low cost, which is desirable for the surface protective film. The deposition temperature is typically 400° Celsius, or more widely, in the range of 150° Celsius to 450° Celsius, to release the excess hydrogen within.

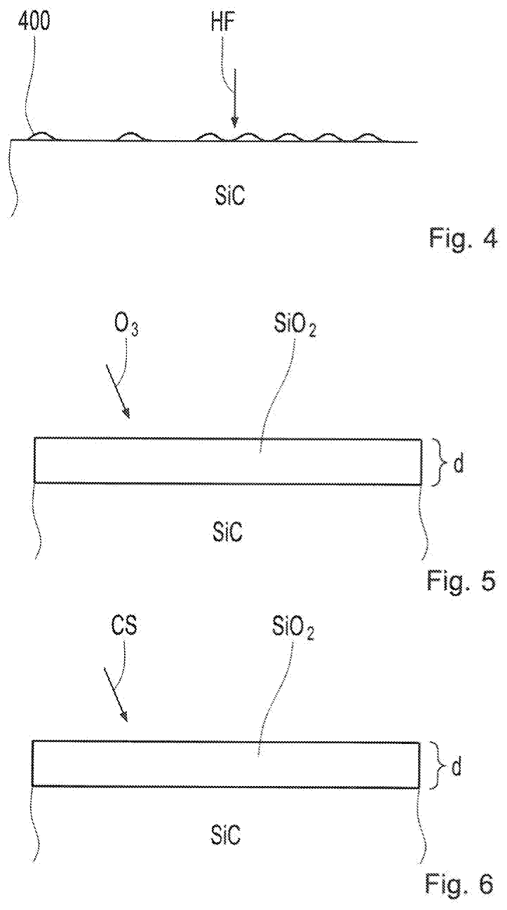

In FIG. 4, it is shown how the residual oxidation layer 400 on the silicon carbide SiC is removed by using hydro fluoric acid HF. This could be in combination with using photoresist defining those areas on the surface of the silicon carbide which should be cleaned by the hydro fluoric acid HF. Photolithography with photoresist is the usual way to pattern semiconductor devices from above. Edging and metallization are applied as needed. For simplicity photolithography is not shown in the figures. Again, this step is performed at a temperature between 0° Celsius and 45° Celsius, preferably at room temperature of 20° Celsius or 21° Celsius.

FIG. 5 shows one embodiment for forming the silicon oxide layer SiO₂ on the silicon carbide SiC. The silicon oxide layer SiO₂having a thickness d. In the example in FIG. 5, the silicon oxide layer SiO₂ is formed by using ozone O₃ at a temperature below 400° Celsius.

FIG. 6 shows an alternative embodiment for forming the silicon oxide layer SiO₂ with the thickness d on the silicon carbide SiC. Here a chemical solution CS is used for forming this layer at a temperature below 400° Celsius. Examples for this chemical solution are mentioned above, for example, a solution could be used which includes nitric acid, hydrogen peroxide, sulfuric acid, hydro fluoric acid, ozone, acetic acid, boiling water, ammonium hydride, or any combination thereof.

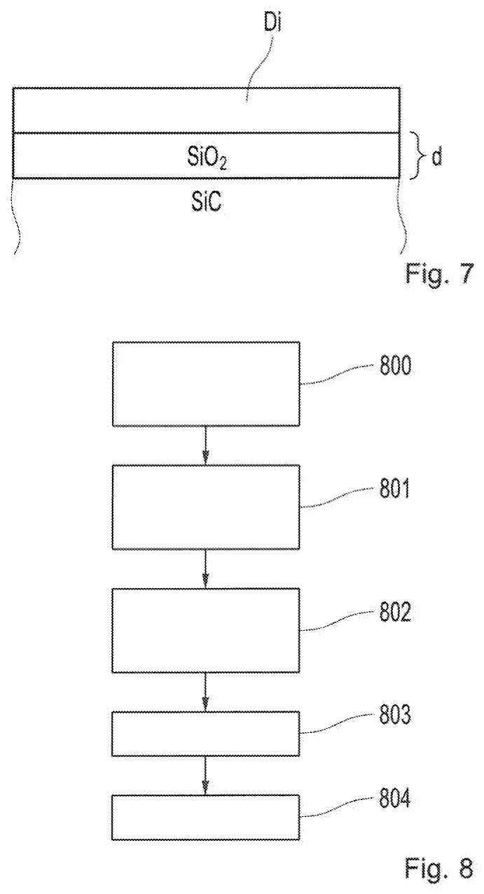

FIG. 7 shows the next step mainly the deposition of the dielectric film Di on the silicon oxide layer SiO₂with the thickness d on the surface of the silicon carbide substrate SiC. The dielectric film Di is made of those elements mentioned above with respect to step 302, and could be deposited by atomic layer deposition or chemical vapor deposition or any other means of depositing such a dielectric film.

The forming of the first thin silicon oxide film is done at temperatures below 400° Celsius, preferably at room temperature from 0° Celsius to 45° Celsius, to avoid thermal stress between the thin silicon oxide and the silicon carbide. The silicon oxide provides excellent interface quality by the following process of dielectric film coating. The dielectric film also complements the thin oxide by having high permittivity and insulating capability. These features will increase the reliability and controllability of this gate structure.

FIG. 8 shows a second flowchart of manufacturing the insulating layer on the silicon carbide. At step 800, similar to step 300 described above, cleaning of the surface of the silicon carbide is performed. At step 801, similar to step 301 described above, a chemical solution is used for forming the first part of the insulating layer, namely the silicon oxide film. After the formation of the silicon oxide, rinsing with water, especially deionized water, and drying the substrate normally follow. Alternatively, the first part of the insulating layer could be also formed by using ozone or O₂ plasma at temperatures below 400° Celsius, preferably at room temperature.

At step 802, similar to step 302 described above, the dielectric film Di is deposited. This is done using atomic layer deposition or chemical vapor deposition or any other means of depositing such a dielectric layer Di, such as, for example, electrodeposition.

At step 803, an annealing of this structure consisting of the silicon oxide layer and the dielectric film is performed at least at 50 Kelvin higher than the deposition of the dielectric layer. A typical annealing temperature is 450° Celsius for a film deposited at 350° Celsius. The annealing step releases excess hydrogen from the deposited film, and part of the hydrogen reaches the interface of the thin silicon oxide and the silicon carbide. The hydrogen improves the film quality of the thin silicon oxide by terminating the dangling bonds in the oxide, and also improves the quality of the interface by terminating the dangling bonds at the surface of the silicon carbide.

At step 804, further steps of manufacturing the semiconductor device with the inventive insulating layer are performed. This includes, for example, the metallization on the dielectric layer in order to have a complete gate structure. In some cases, one of these further steps, for example a sintering process of the metal electrode, can also be the annealing step 803 if the process condition satisfies the requirement. In other words, one annealing step in the further steps can perform at least the termination of dangling bonds in the thin oxide and the surface of the silicon carbide of step 803. This means no additional cost is required for the annealing step 803.

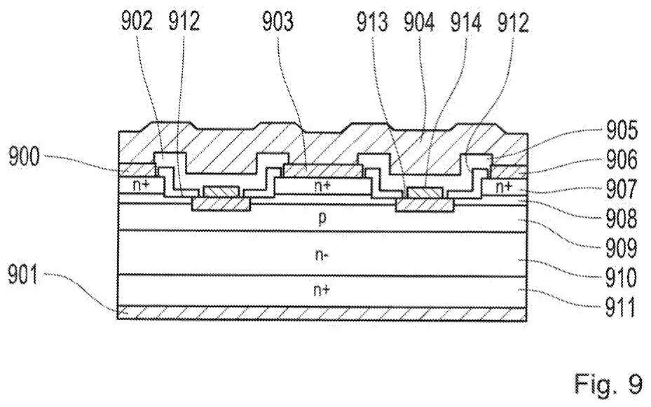

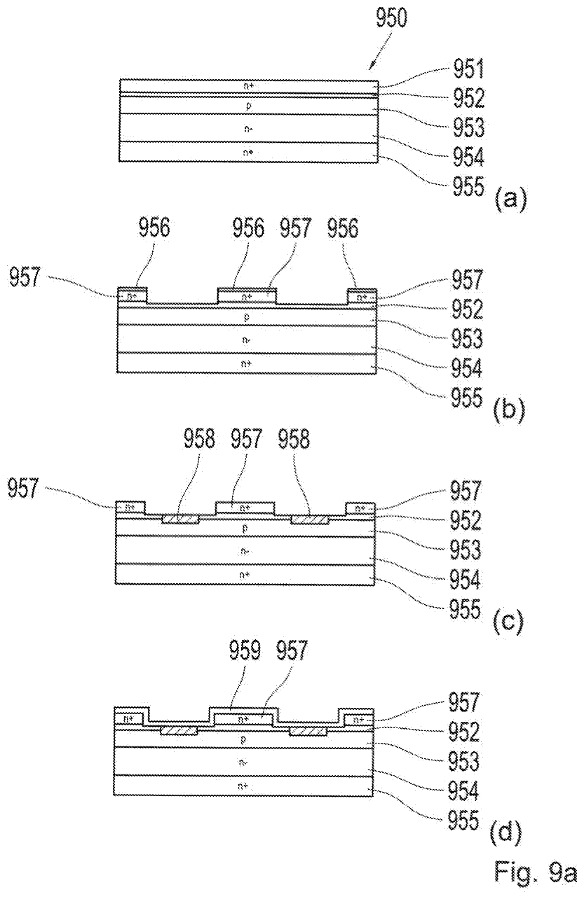

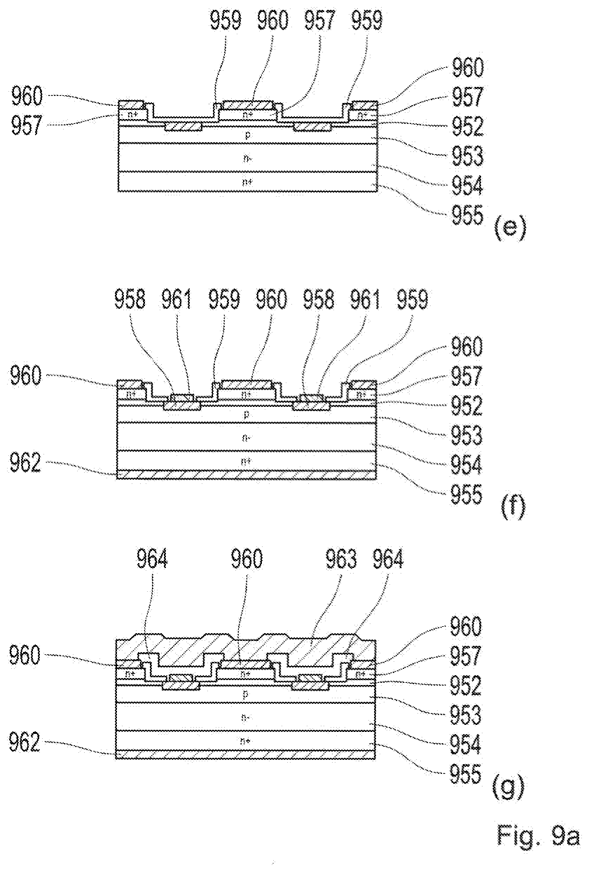

FIG. 9 shows a cross section of a bipolar junction transistor (BJT). An n+ type low resistance substrate 911 is used on the lower side of the BJT and serves as a collector region. The n− type high resistance layer 910 is epitaxially grown on this substrate to a thickness of 10 micrometers (μm). By further epitaxial growth a channel doped p type layer 909 is deposited up to a thickness of 0.1 micrometers to 0.5 micrometers. On this a base p type layer 908 is deposited. Finally, a low resistance contact n+ type layer 907 is grown on the base layer 908. After the growth of n+ type layer 907, designated regions are removed using reactive ion etching (RIE). The remaining regions of the low resistance contact 907 are protected from RIE by an etching mask which is typically a deposited silicon oxide film patterned with photo-lithography. With this RIE step, the side wall of a mesa of the low resistance contact 907 and part of the base layer 908 are exposed, together with the surface of the base layer 908. On other designated regions of the exposed surface of the base layer 908, a p+ base contact region 913 is formed using local ion implantation and post-implantation annealing.

After removing a carbon capping layer required at the post-implantation annealing by O₂ plasma treatment, sacrificial oxidation is carried out at 1100° Celsius for 20 hours. Then this sacrificial oxide is removed by HF solution, the insulation layer 912 according to the present subject matter is formed on the top of the low resistance contact 907, the mesa wall of the low resistance contact 907 and the base layer 908, and the top of the base layer 908 and the base contact region 913. Furthermore, contact regions for the low resistance contact 907 and the base contact region 913 are formed by local RIE of the insulation layer 912 with photolithography-designed etching masks. Then an emitter metal 900, 903, 906 is formed on the mesa top of the low resistance contact or emitter 907; a base metal 914 is formed on the p+ base contact region 913; and a collector metal 901 is formed underneath the n+ substrate 911. Heat treatment is performed to reduce contact resistance of the electrodes, including emitter metal 906, base metal 914, and collector metal 901. An interlayer 902 made of silicon oxide is deposited above the insulation layer 912, base metal 914, and emitter metal 903. After contact regions for the emitter metal 903 are formed on the interlayer 902, the upper electrode 904 is made as emitter metal.

FIG. 9a shows sequential steps of how a BJT is manufactured according to the present subject matter. A laminated structure shown in FIG. 9a(a) is formed by carrying out the manufacturing steps in order. In the substrate preparation process, an n+ type low-resistance substrate (crystal) 955 for forming a SiC semiconductor element is prepared. The substrate 955 is located on the lower side of the BJT shown in the drawings and serves as a collector region composed of an n-type low-resistance layer. In the process of formation of an n− type high-resistance layer, a high-resistance layer 954 doped with nitrogen to a concentration of 1×10¹⁶ cm⁻³ as an impurity is grown to a thickness of 10 micrometers on the substrate 955 for forming a SiC semiconductor element by epitaxial growth.

In the process of formation of a channel dope layer, a p type channel dope region 953 doped with aluminum (Al) to a concentration of 4×10¹⁷ to 2×10¹⁸ cm⁻³ as an impurity is grown to a thickness of 0.1 to 0.5 micrometers on the high-resistance layer 954 by epitaxial growth.

In the process of formation of a base region, a p type base region 952 is further similarly grown on the channel dope layer 953 by epitaxial growth.

In the process of formation of a low-resistance layer, an n+ type low-resistance layer 951 doped with nitrogen to a concentration of 1×10¹⁹ cm⁻³ to 5×10¹⁹ cm⁻³ as an impurity is grown to a thickness of 0.5 to 2.0 micrometers on the base region 952 by epitaxial growth. This low-resistance layer 951 will be etched later to form an emitter region.

In the next emitter-etching process, shown in FIG. 9a(b), a silicon dioxide film 956 is deposited on the upper surface of the laminated structure by CVD, and is then subjected to photolithography, and is then further dry-etched by RIE to form an etching mask (not shown). Then, the low-resistance layer 951 is subjected to SiC etching by RIE using the etching mask made of the silicon dioxide film 956 to form an emitter region 957 using the low-resistance layer 951.The RIE for SiC etching is performed in an atmosphere of, for example, HBr gas, Cl₂ gas, or H₂/O₂ gas, and the etching depth is 0.5 to 2.1 micrometers. The thus obtained structure is shown in FIG. 9a(b).

In the process of formation of an ion implantation mask, implantation of high-concentration ions for base contact and activation heat treatment, the following treatments are performed, respectively.

Ion Implantation Mask

A mask is formed to have openings to expose the surface of the base region 952 where a base contact region 958 is to be formed. The mask is formed by depositing a silicon dioxide film by CVD, performing photolithography, and dry-etching the silicon dioxide film by RIE. It is to be noted that the mask is not shown in FIG. 9a(c, instead only the resulting base contact region 958 is shown.

Implantation of High-Concentration Ions for Base Contact

In the process of formation of the base contact region 958, ion implantation is performed using the above mentioned ion implantation mask to form the base contact region 958. For example, aluminum (Al) ions are implanted. The implantation depth is, for example, 0.2 micrometers. The amount of ions to be implanted is 1×10¹⁸ cm⁻³ to 1×10¹⁹ cm⁻³, and ions are implanted at a maximum energy of about 400 kilo-electron volts (KeV) in multiple stages.

Activation Heat Treatment

In the process of activation of an ion-implanted layer, heat treatment is performed after ion implantation to electrically activate implanted ions in the semiconductor and to eliminate crystal defects induced by ion implantation. This activation heat treatment activates both implanted ions in the base contact region 958 and implanted ions in a recombination inhibiting region at the same time. More specifically, the activation heat treatment is performed using, for example, a high-frequency heat treatment furnace at a high temperature of about 1700° Celsius to 1900° Celsius for about 10 minutes to 30 minutes in an atmosphere of, for example, argon Ar gas, or under vacuum.

The process of insulation layer formation which consists of silicon carbide surface preparation, low-temperature surface oxidation, and deposition of a dielectric film will be described below. In FIG. 9a(d), the reference numeral 959 denotes the surface insulation layer. In the process formation of insulation layer, the following treatments are performed, respectively.

Sacrificial Oxidation and Preparation of the Surface

Surface preparation is performed on the uppermost SiC surface of the BJT shown in FIG. 9a(c). In the preparation step, the SiC surface is first subjected to sacrificial oxidation to remove the layer damaged by ion bombardment at the RIE step. The sacrificial oxidation is performed, for example, at a temperature of 1100° Celsius for 20 hours to form a sacrificial oxide film on the SiC surface. Then, the sacrificial oxide film is removed by 50% HF solution afterwards, and SiC surfaces without ion bombardment damage of the base contact region 958, base region 952, and emitter region 957 are exposed at the regions where the layer damaged by ion bombardment at the RIE step was locally removed.

Low Temperature Oxidation

Then, low temperature oxidation on the prepared SiC surface according to the present subject matter is performed at a temperature of 350° Celsius while being exposed to an ozone-included atmosphere for 2 hours. This process can be substituted by a wet process like dipping in a 68% HNO₃ solution at a temperature of 121° Celsius for 1 hour. The temperature can also be at a room temperature, although it requires longer duration, about 4 hours. In case of wet process, the process should be followed by rinsing in deionized water and drying. In this way, a thin silicon oxide film having a thickness of approximately 2 nanometers is formed on the SiC surface of the BJT.

Deposition of a Dielectric Film

A dielectric film according to the present subject matter is deposited on the thin silicon oxide film. In this embodiment, a silicon nitride film as the dielectric film is deposited with plasma-enhanced CVD. A typical deposition condition is to place the processed SiC at a cathode side of a parallel plate substrate holder in a reaction chamber; keeping the substrate holder temperature at 375° Celsius; introducing mixture gases of silane, ammonia, and nitrogen into the chamber; and applying AC voltage with a frequency of 2.45 GHz to the anode. Thus, plasma of the mixture gases is induced between the anode and the cathode of the parallel plate, and chemical reaction for silicon nitride film deposition is enhanced by the plasma, until the silicon nitride film is deposited thicker than 150 nanometers.

In this way, the insulation layer 959 (shown in FIGS. 9a(d), 9a(e), 9a(f), and 9a(g)) having a laminated structure composed of the thin silicon oxide film and the deposited dielectric film is formed on the exposed SiC surface of the BJT. More specifically the thin silicon oxide film and the deposited dielectric film are formed on the SiC surface extending from the emitter region 957 except for emitter electrodes 960 to the base contact region 958 except for a base electrode 961. By forming these films, it is possible to deactivate the surface and to suppress the generation of surface states formed at the SiC surface region.

The film thickness of the deposited dielectric film is preferably 150 nanometers or more, more preferably 150 nanometers to 1000 nanometers. If the film thickness of the deposited dielectric film is less than 150 nanometers, that is, less than the film thicknesses of electrodes, it is not easy to form electrodes by, for example, a lift-off method. In addition, there is also a case where electrical breakdown of the surface insulation layer occurs when a high voltage is applied to the semiconductor element. On the other hand, if the film thickness of the deposited dielectric film exceeds 1000 nanometers, processing time increases, which increases manufacturing costs.

Emitter Electrode Formation

In the process of formation of emitter electrodes, emitter electrodes 960 are formed on the surface of the emitter region 957 (low-resistance layer 951) (FIG. 9a(e)). The emitter electrodes 960 are formed by vapor deposition or sputtering using nickel or titanium. An electrode pattern is formed by photolithography, dry-etching, wet-etching, or a lift-off method. After the emitter electrodes 960 are formed, heat treatment is performed to reduce contact resistance between the metal and the semiconductor.

Base and Collector Electrodes Formation

In the process of formation of a base electrode and a collector electrode, a base electrode 961 is formed on the surface of the base contact region 958 and a collector electrode 962 is formed on the surface of the collector region 955 (substrate 955) (FIG. 9a(f)). The collector electrode 962 is formed using nickel or titanium and the base electrode 961 is formed using titanium or aluminum. These electrodes 961 and 962 are formed by vapor deposition or sputtering. An electrode pattern is formed by photolithography, dry-etching, wet-etching, or a lift-off method.

Electrodes Sintering

After the electrodes 961 and 962 are formed, heat treatment, which is at a temperature of 450° Celsius for 1 hour, is performed to reduce contact resistance between the metal and the semiconductor. Besides reducing the contact resistance, according to the present subject matter, this heat treatment induces the deposited dielectric film (upper side of the insulation layer 959) to emit downwards hydrogen molecules which improve the film quality of the thin silicon oxide (lower side of the insulation layer 959) and enhance the surface deactivation of the base 952 and the emitter 957 as the interface with the insulation layer 959.

Finally, the process of formation of an interlayer film and an upper-layer electrode is performed. In the process of formation of an interlayer film and an upper-layer electrode, an upper-layer electrode 963 is formed to allow the separated two or more emitter electrodes 960 to function as one electrode (FIG. 9a(g)). More specifically, an interlayer 964 such as a silicon dioxide film is formed by CVD, and then the silicon dioxide film formed on the emitter electrodes 960 is removed by photolithography and etching to expose the emitter electrodes 960. Then, the upper-layer electrode 963 is deposited on the emitter electrodes 960 and the interlayer 964. The upper-layer electrode 963 is made of, for example, aluminum (Al).

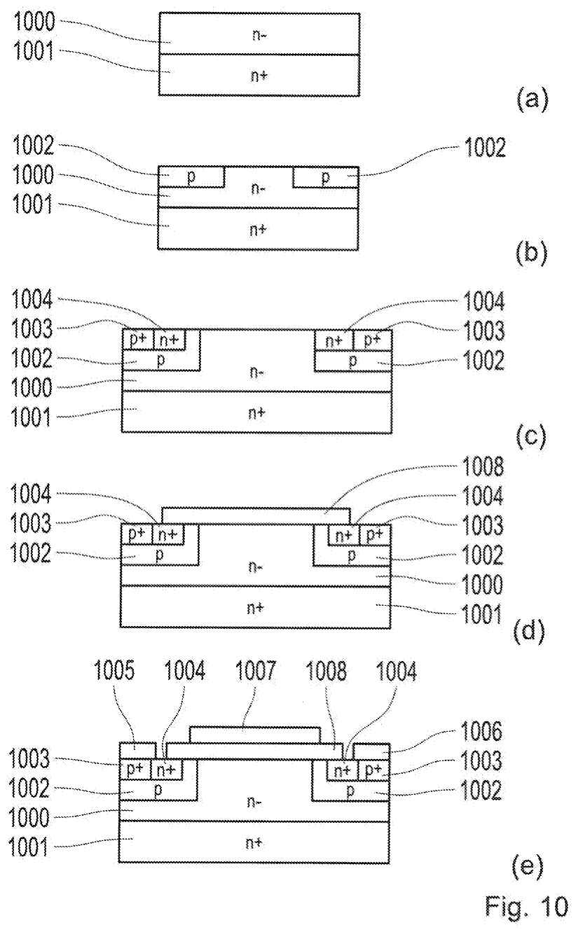

FIG. 10 shows sequential steps of the inventive method manufacturing a DMOSFET, or a MOSFET with a plane gate. In a first step, shown in FIG. 10(a), a high resistance n− type layer 1000 is epitaxially grown on a low resistance n+ type substrate 1001. In a second step, shown in FIG. 10 (b), two p type wells 1002 are formed in the n− type layer 1000. In a third step, shown in FIG. 10(c), in the two p type wells a contact region 1003 with p+ doping and an n+ source region 1004 are respectively formed by local ion implantation, followed by post-implantation annealing with a carbon-capping film to prevent surface roughening. After the carbon-capping film is removed by O₂ plasma treatment, the surfaces of the n− type layer 1000, p type wells 1002, and n+ source region 1004 are prepared by HF solution treatment.

The insulation layer 1008 is formed on the surfaces of the n− type layer 1000, p type wells 1002, and n+ source region 1004 according to the present subject matter as described above as shown in a fourth step in FIG. 10(d). Subsequent photolithography and an etching process removes the insulation layer 1008 formed on the surfaces of the contact region 1003 and the part of the surface of the n+ source region 1004.

Finally in a fifth step, shown in FIG. 10(e), source metallization 1005, 1006 on top of the contact region 1003 and partly on the source region 1004 is deposited. A gate metallization 1007 is deposited on top of the insulation layer 1008. A drain metallization is formed underneath the n+ substrate 1001.

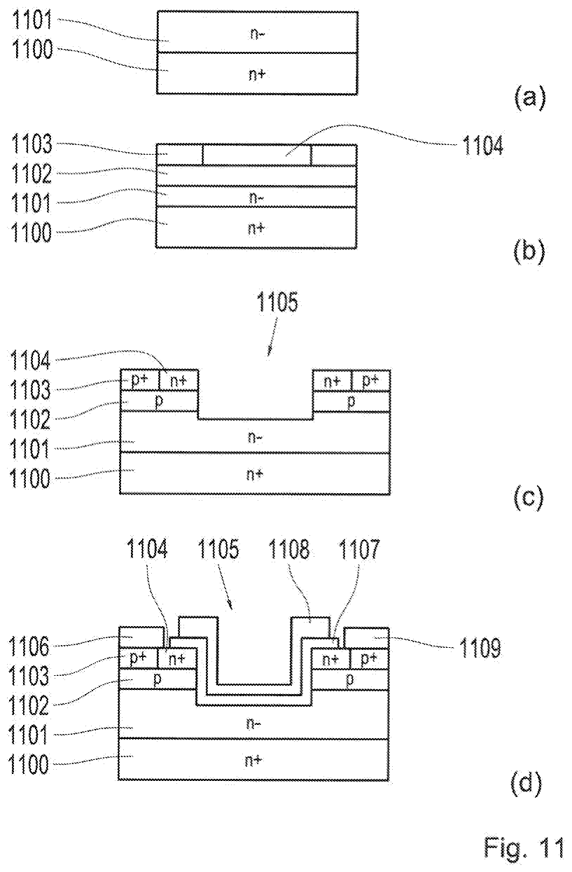

FIG. 11 shows sequential steps of the inventive method manufacturing a UMOSFET, or a MOSFET with a trench gate. In a first step, shown in FIG. 11(a), a high resistance n− type layer 1101 is epitaxially grown on a low resistance n+ type substrate 1100. In a second step, shown in FIG. 11(b), on top of the layer 1101 a p type layer 1102 is epitaxially grown. A contact region 1103 of p+ type and the n+ type source region 1104 are formed by local ion implantation and post-implantation annealing. In a third step, shown in FIG. 11(c), a trench 1105 is etched down to the n− type layer 1101 by RIE. Then sacrificial oxidation is carried out and the sacrificial oxide is removed later to expose high-quality surface in the trench. In this trench 1105 up to the source region 1104, an insulation film 1107 according to the present subject matter is formed in a fourth step, shown in FIG. 11(d). On top of the insulation layer 1107, the gate metallization 1108 is deposited. A source metallization 1106, 1109 on the top of the p+ contact 1103 and partly on the n+ source 1104 is deposited. A drain metallization is formed underneath the n+ substrate 1100.

Modifications and variations can be made to the embodiments illustrated or described herein without departing from the scope and spirit of the invention as set forth in the appended claims.

### REFERENCE NUMERALS

10 Source electrode

11 contact region

12 source region

13 gate metallization

14 insulation layer

15 p-type base layer

16 n− type layer

17 n type layer

18 n+ type substrate

19 drain metallization

20 source electrode

21 contact region

22 n+ type source region

23 gate metallization

24 insulation layer

25 p-type base layer

26 n-type layer

27 n+ type substrate

28 drain metallization

300 Preparing a surface of the SiC

301 Forming first part of the insulation layer

302 Depositing dielectric film on first part

400 native oxide layer

d thickness of silicon oxide layer

800 Cleaning

801 Chemical solution

802 Depositing dielectric film

803 annealing

804 further steps

900 metallization

901 metallization

902, 905 interlayer

903, 906 metallization

904 metallization

907 contact region

908 base layer

909 channel doped layer

910 n− type high resistance layer

911 n+ type substrate

912 insulation

913 p+ base contact region

914 metallization

1000 n− type layer

1001 n+ type substrate

1002 p well

1003 contact region

1004 source region

1005 metallization

1006 metallization

1007 metallization

1008 insulation layer

1100 n+ type substrate

1101 n− type layer

1102 p type layer

1103 contact region

1104 source region

1105 trench

1106, 1109 metallization

1107 insulation layer

1108 metallization

1-11. (canceled)

12. A method of manufacturing an insulation layer on a silicon carbide substrate, the method comprising:
preparing a surface of a silicon carbide substrate;
forming a first part of an insulation layer on the surface of the silicon carbide substrate at a temperature below 400° Celsius; and
forming a second part of the insulation layer by depositing a dielectric film on the first part of the insulation layer.

13. The method of claim 12, wherein preparing the surface of the silicon carbide substrate comprises removing an oxide on the surface of the silicon carbide substrate.

14. The method of claim 12, wherein the first part of the insulation layer is a silicon oxide film.

15. The method of claim 14, wherein the silicon oxide film has a thickness between 0.5 nanometers and 10 nanometers.

16. The method of claim 14, wherein forming the silicon oxide film comprises bringing the surface of the silicon carbide substrate into contact with a chemical solution or exposing the surface of the silicon carbide substrate to ozone or oxygen plasma.

17. The method of claim 12, wherein the temperature is between 0° and 45° Celsius.

18. The method of claim 12, wherein the dielectric film is deposited by an atomic layer deposition or by a chemical vapor deposition.

19. The method according to any of claim 12, further comprising, after depositing the dielectric film, annealing the insulation layer on the silicon carbide substrate at a temperature that is at least 50 Kelvin greater than a peak temperature during the deposition of the dielectric film.

20. A semiconductor device, comprising:
a silicon carbide substrate, and
an insulation layer formed at least partly on the silicon carbide substrate, the insulation layer comprising a silicon oxide layer and a dielectric layer deposited on the silicon oxide layer,
wherein the silicon oxide layer has a thickness between 0.5 nanometers and 10 nanometers.

21. The semiconductor device of claim 20, wherein the semiconductor device is a field effect transistor.

22. The semiconductor device of claim 20, wherein the semiconductor device is a bipolar junction transistor.
